(19) United States
(12) Patent Application Publication
(10) Pub. No.: US 2026/0371811 A1
(43) Pub. Date: Nov. 19, 2026

(54) DISPLAY DEVICE AND MANUFACTURING METHOD THEREFOR

(71) Applicant: LG ELECTRONICS INC., Seoul (KR)

(72) Inventors: Naree KIM, Seoul (KR); Hongkey PARK, Seoul (KR); Hyunjong KIM, Seoul (KR); Jihoon LEE, Seoul (KR); Jeongsik CHOI, Seoul (KR)

(73) Assignee: LG ELECTRONICS INC., Seoul (KR)

(21) Appl. No.: 19/124,084

(22) PCT Filed: Nov. 10, 2023
(86) PCT No.: PCT/KR2023/018073

§ 371 Date: Apr. 24, 2025

(30) Foreign Application Priority Data
Nov. 11, 2022 (KR) 10-2022-0150499

(51) Int. Cl. H10H 29/49; H10H 29/01; H10H 29/855

(52) U.S. Cl. CPC H10H 29/49; H10H 29/012; H10H 29/0363; H10H 29/8552

(57) ABSTRACT

The present disclosure is applicable to the technical field related to display devices, and relates to a display device using, for example, light-emitting diodes (LED), and a manufacturing method therefor. This disclosure may comprise: a wiring substrate; an electrode pad that is partitioned on the wiring substrate to constitute a plurality of unit pixels; a light-emitting diode that is connected to the electrode pad; an encapsulation layer that is formed on the wiring substrate so as to cover the light emitting diode; a black coating layer that is located on a side of the encapsulation layer and contains a black pigment in a resin-based base coating agent; and an optical film that is located on the encapsulation layer.

### TECHNICAL FIELD

The present disclosure is applicable to a technical field related to a display device, and relates to, for example, a display device using a light emitting diode (LED) and a manufacturing method thereof.

### BACKGROUND

As the information society develops, demand for a display device increases in various forms, and in response thereto, various display devices such as a Liquid Crystal Display (LCD) device, a Plasma Display Panel (PDP), an Electro Luminescent Display (ELD), a Vacuum Fluorescent Display (VFD), an Organic Light Emitting Diode (OLED), a Micro Light Emitting Diode (Micro LED), and the like are being studied and used.

A digital signage is a display device that provides specific information as well as a broadcasting program in public places such as airport, hotel, hospital, and subway station, and the like, as a communication tool capable of inducing marketing, advertisement, training effects, and customer experience of enterprises as well as a general TV.

A digital signage is a medium for displaying various contents and commercial advertisements by installing a display panel such as a Liquid Crystal Display (LCD), a Plasma Display Panel (PDP), an Organic Light Emitting Diode (OLED), a Micro LED Light Emitting Diode (LED), etc. in certain outdoor places or devices such as street furniture, and may be installed on public movement lines such as apartment elevators, subway stations, subway trains, buses, universities, banks, convenience stores, discount stores, and shopping malls, and the like.

Recently, many studies have been conducted to improve an image quality of a display panel while the digital signage is large- or ultra-large sized.

Such digital signage is implemented as a modular display device in which various display modules are configured to be combined. Such a module display may use a Light Emitting Diode (LED) as a pixel.

FIG. 1 schematically illustrates an example of a modular display device configured by combining a plurality of general display modules.

Referring to FIG. 1, a modular display device 1 is shown in which a plurality of display modules 2 are combined to form a large area.

However, in such a display device 1, a phenomenon in which bright lines A and B are visible may occur due to light augment of a light source LED at a side joint of the module 2.

For example, when connecting small-sized display modules 2 to each other to form a large-sized display device 1, a phenomenon may occur in which a joint portion of the display modules 2 appears as a brighter line than other surfaces. This phenomenon may hinder visibility as small display modules 2 that are combined together appear to be connected as a single display. Therefore, solutions to resolve these problems have emerged.

### DISCLOSURE

### Technical Problem

An object of an embodiment of the present disclosure is to provide a display device and a manufacturing method thereof for preventing a phenomenon in which a joint portion of a unit display device appears as a bright line compared to other surfaces when a plurality of unit display devices are combined with each other in a planar direction to form a larger display device.

An object of an embodiment of the present disclosure is to provide a display device and a manufacturing method thereof in which a plurality of unit display devices combined with each other are connected to each other as a single display without obstructing visibility when the plurality of unit display devices are combined with each other in a plane direction to form a larger display device.

### Technical Solution

To achieve the objects described above, according to a first aspect of the present disclosure, a display device includes a wiring substrate, an electrode pad partitioned on the wiring substrate to form a plurality of unit pixels, a light-emitting element connected to the electrode pad, an encapsulation layer formed on the wiring substrate to cover the light-emitting element, a black coating layer located on a lateral surface of the encapsulation layer and including a black pigment in a resin-based base coating agent, and an optical film located on the encapsulation layer.

As an exemplary embodiment, the base coating agent may include acrylic, silicone, or acrylic resin.

As an exemplary embodiment, the black pigment in the black coating layer may have a content of 0.01 to 5 wt %.

As an exemplary embodiment, separate particles of the black pigment may have a size of 20 nm to 3 μm.

As an exemplary embodiment, a height of the black coating layer may be identical to a thickness of the encapsulation layer.

As an exemplary embodiment, a thickness of the black coating layer may be 10 to 30 μm.

As an exemplary embodiment, a ratio of a thickness of the black coating layer to a thickness of the encapsulation layer may be 2 to 21%.

As an exemplary embodiment, the display device may further include a light scattering agent distributed in at least one of the encapsulation layer or the optical layer.

As an exemplary embodiment, the light scattering agent may include at least one of zirconium (Zr), silicon (Si), titanium (Ti), zinc (Zn), BaS, or an oxide thereof.

As an exemplary embodiment, the optical layer may include an optically transparent adhesive layer, and an anti glare (AG) and anti fingerprint (AF) functional coating located on the optically transparent adhesive layer.

To achieve the objects described above, according to a second aspect of the present disclosure, a method of manufacturing a display device includes providing an assembly including a wiring substrate, an electrode pad partitioned on the wiring substrate to form a plurality of unit pixels, a light-emitting element connected to the electrode pad, and an encapsulation layer formed on the wiring substrate to cover the plurality of light-emitting elements, and forming a black coating layer on a lateral surface of the encapsulation layer by stamping coating ink including a resin-based base coating agent.

As an exemplary embodiment, the coating ink may include a terminal functional group for improving adhesion to the encapsulation layer.

As an exemplary embodiment, the terminal functional group may have a content of 0.001 to 10 wt % with respect to the entire black coating layer.

### Advantageous Effects

According to an exemplary embodiment of the present disclosure, the following effects are achieved.

First, when a plurality of unit display devices are combined with each other in a planar direction to form a larger display device, a phenomenon in which a joint portion of the unit display devices appears as a bright line compared to other surfaces may be prevented.

Accordingly, the plurality of display devices combined with each other may be connected to appear as a single display without obstructing visibility.

### BRIEF DESCRIPTION OF THE DRAWINGS

FIG. 1 schematically illustrates an example of a modular display device configured by combining a plurality of general display modules.

FIG. 2 is a schematic cross-sectional view showing a display device according to a first embodiment of the present disclosure.

FIG. 3 and FIG. 4 are schematic cross-sectional views showing a process of manufacturing a display device according to the first embodiment of the present disclosure.

FIG. 5 is a schematic cross-sectional view showing a display device according to a second embodiment of the present disclosure.

FIG. 6 is an enlarged view of the black coating layer of FIG. 5.

FIG. 7 is a photograph showing examples of a black coating layer formed by a stamping process.

FIG. 8 is a cross-sectional view showing a display device according to the second embodiment of the present disclosure.

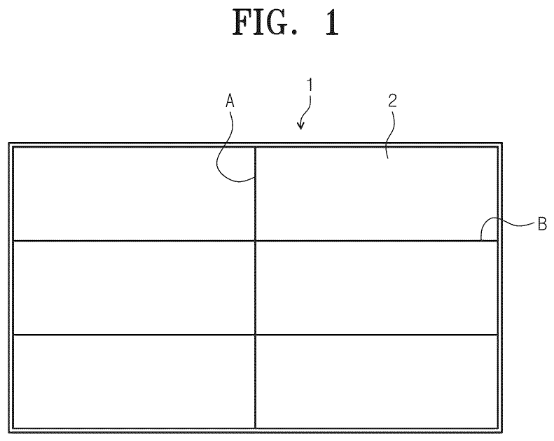

### DETAILED DESCRIPTION

Reference will now be made in detail to embodiments of the present disclosure, examples of which are illustrated in the accompanying drawings. Wherever possible, the same reference numbers will be used throughout the drawings to refer to the same or like parts, and redundant description thereof will be omitted. As used herein, the suffixes “module” and “unit” are added or used interchangeably to facilitate preparation of this specification and are not intended to suggest distinct meanings or functions.

In describing embodiments disclosed in this specification, relevant well-known technologies may not be described in detail in order not to obscure the subject matter of the embodiments disclosed in this specification.

As used herein, the suffixes “module” and “unit” are added or used interchangeably to facilitate preparation of this specification and are not intended to suggest distinct meanings or functions. In describing embodiments disclosed in this specification, relevant well-known technologies may not be described in detail in order not to obscure the subject matter of the embodiments disclosed in this specification. In addition, it should be noted that the accompanying drawings are only for easy understanding of the embodiments disclosed in the present specification, and should not be construed as limiting the technical spirit disclosed in the present specification.

Furthermore, although the drawings are separately described for simplicity, embodiments implemented by combining at least two or more drawings are also within the scope of the present disclosure.

In addition, when an element such as a layer, region or module is described as being “on” another element, it is to be understood that the element may be directly on the other element or there may be an intermediate element between them.

A display device described in the present specification is a concept including all display devices displaying information as a unit pixel or a set of unit pixels. Therefore, the present disclosure is not limited to a finished product and may be applicable to a component. For example, a panel corresponding to one component of a digital TV may also independently correspond to a display device of the present specification. The finished product may include a mobile phone, a smart phone, a laptop computer, a digital broadcasting terminal, Personal Digital Assistants (PDA), a Portable Multimedia Player (PMP), a navigation, a slate PC, a tablet PC, an Ultra Book, a digital TV, a desktop computer, etc.

However, it will be readily apparent to those skilled in the art that the configuration according to embodiments described herein may be applied to a device capable of displaying even in the form of a new product to be developed later.

In addition, the semiconductor light emitting device mentioned in this specification is a concept including an LED, a micro LED, and the like, which may be used in a mixed manner.

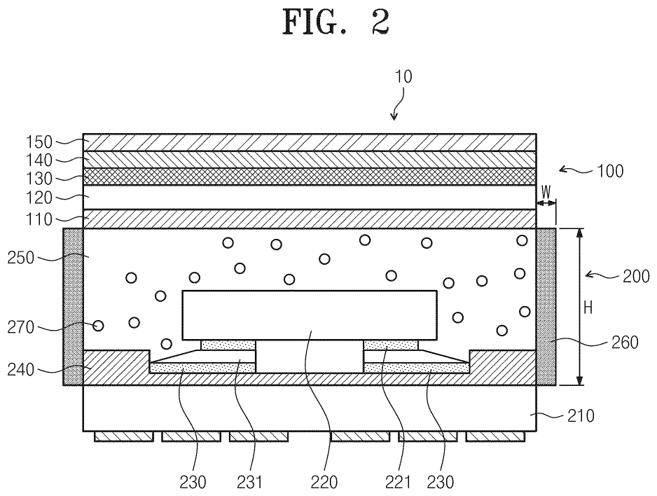

FIG. 2 is a schematic cross-sectional view showing a display device according to a first embodiment of the present disclosure.

As illustrated in FIG. 2, a display device 10 may largely include a display panel 200 and an optical layer 100 disposed on the display panel 200.

The display panel 200 may include light-emitting elements 220 arranged on a wiring substrate 210 to form a unit subpixel or pixel. A display image may be implemented by an arrangement of the light-emitting elements 220 that form the unit subpixel or pixel.

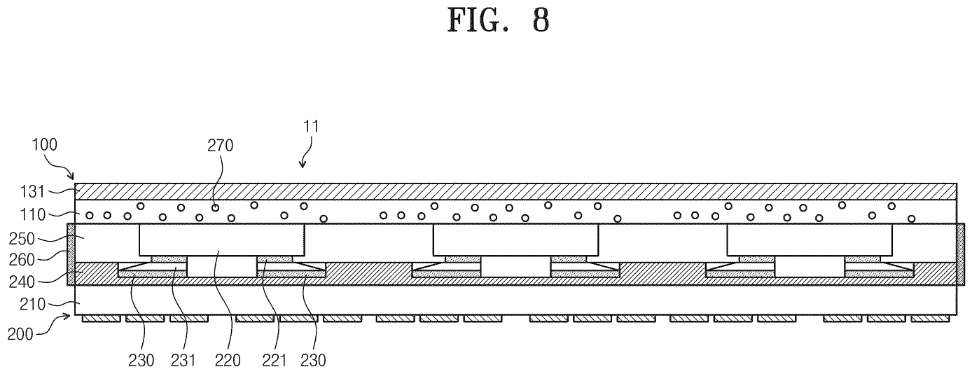

In FIG. 2, one light-emitting element 220 is illustrated, but a plurality of light-emitting elements 220 that form a unit subpixel or pixel may be provided (see FIG. 8).

As such, the unit subpixel may be configured by separate light-emitting elements 220. For example, the light-emitting elements 220 constituting the unit subpixel may include a red light-emitting element, a green light-emitting element, and a blue light-emitting element.

The separate light-emitting element 220 may be electrically connected to a unit electrode pad 230 located on the wiring substrate 210 by an electric joint such as a solder 231. That is, two electrodes 221 of the light-emitting elements 220 may electrically connected to a pair of unit electrode pads 230, respectively.

The light-emitting element 220 may include a stack-type light-emitting element (LED) in which red, green, and blue light-emitting diodes are formed into a single chip structure. The stack-type light-emitting element 220 may implement a unit pixel.

In FIG. 2, a component located at a lower end of the wiring substrate 210 may be a driver integrated circuit (IC) for driving the light-emitting element 220. A description thereof is omitted.

An encapsulation layer 250 may be located on the light-emitting element 220. The encapsulation layer 250 may be located on the wiring substrate 210 provided with an electrode pad 230. The encapsulation layer 250 may include an insulating and flexible material, such as polyimide (PI), polyethylene terephthalate (PET), polyethylene naphthalate (PEN), or silicone, and may be formed integrally with the wiring substrate 210 to form a single board. As such, the wiring substrate 210 provided with the electrode pad 230 may include a wiring electrode (not shown) connected to the electrode pad 230. A detailed description thereof is omitted.

For example, a thin film transistor (TFT) may be connected to a wiring electrode to implement an active matrix (AM) type display device. For example, the wiring substrate 210 may be a thin film transistor (TFT) board. As another example, the wiring substrate 210 may be a passive matrix (PM)-type board.

The encapsulation layer 250 may include a filler 270. The filler 270 may have optical properties that refract or scatter light emitted from the light-emitting element 220.

Light emitted from the light-emitting element 220 may be refracted or scattered by the filler 270. Light scattered from the filler 270 may be emitted to the outside of the encapsulation layer 250.

The encapsulation layer 250 may have light-transmitting properties after being cured. For example, the cured encapsulation layer 250 including silicone may have a refractive index of 1.4 to 1.6. Accordingly, light may be totally reflected inside the encapsulation layer 250. The filler 270 may refract or scatter light that is totally reflected within the encapsulation layer 250.

That is, the filler 270 may act as a light scattering agent. Therefore, the filler 270 may be called a light scattering agent. In the following description, a filler and a light scattering agent may mean the same object.

The filler (270) may include at least one of zirconium (Zr), silicon (Si), titanium (Ti), zinc (Zn), BaS, or an oxide thereof. For example, the filler 270 may be spherical or amorphous.

A diameter or size of the filler 270 may be 10 nanometers (nm) to 10 micrometers (μm). The content (weight ratio) of the filler 270 may be 0.01% to 30% relative to the encapsulation layer 250. For example, the filler 270 may include at least one of Zr oxide or Si oxide.

Although not shown separately, a modular display device in which a plurality of display devices 10 are combined to implement a larger display area may be implemented. For example, the display device 10 may be one display module forming a modular display device. As such, the plurality of display devices 10 may be connected in parallel to form a modular display device. A detailed description thereof is omitted.

The optical layer 100 may be located on the display panel 200. The optical layer 100 may form a composite optical film. As such, the optical layer 100 may be attached to the display panel 200. The display panel 200 to which the optical layer 100 is attached may be referred to as the display device 10.

Here, the optical layer 100 may include, as an exemplary embodiment, an optically transparent adhesive layer (OCA) 110 attached to the display panel 200.

At least one of a colorless polyimide (CPI) film 120, a black dye layer 130, an anti glare (AG) coating layer 140, or an anti fingerprint (AF) coating layer 150 may be further provided on the OCA 110.

For example, a composite optical film including the CPI film 120, the black coating layer 130, the AG coating layer 140, and the AF coating layer 150 may be attached to the encapsulation layer 250 by the OCA 110.

A black coating layer 260 containing black pigment within a resin-based base coating agent may be located on a lateral surface of the encapsulation layer 250. Here, the base coating agent may include acrylic, silicone, or acrylic resin. A transmittance of the black coating layer 260 may be 25 to 60%.

As an exemplary embodiment, the black pigment in the black coating layer 260 may have a content of 0.01 to 5 wt % (weight percent; parts by weight). For example, the black coating layer 260 may be formed by applying a base coating agent containing a black pigment. The black coating layer 260 may be formed by a stamping method. This will be described in more detail below.

After the base coating agent containing the black pigment is cured, the black pigment in the black coating layer 260 may have a content of 0.01 to 5 wt %. As an exemplary embodiment, separate particles of the black pigment within the black coating layer 260 may have a size of 20 nm to 3 μm.

The hardness of the base coating agent may be A30 to D60 based on a Shore hardness meter. In the Shore hardness meter, a higher number indicates greater hardness, with D having greater hardness than A.

In the present embodiment, the performance may be maintained when a surface rubbing test (based on 1 kgf 30 times) is performed 100 times at A30 or higher. It may be seen that a material with hardness less than A30 has surface damage in the surface rubbing test.

As an exemplary embodiment, a height H of the black coating layer 260 may match a thickness of the encapsulation layer 250. In reality, the lateral surface of the encapsulation layer 250 on which the light-emitting element 220 is located may be coated with the black coating layer 260. As an exemplary embodiment, a thickness W of the black coating layer 260 may be 10 to 30 μm.

When the black coating layer 260 having at least one of the height H or the thicknesses W is provided, if the plurality of display devices 10 are combined to each other in a planar direction to form a larger display device, a phenomenon in which a joint portion of the display devices 10 appears as a bright line compared to other surfaces may be prevented. Accordingly, the plurality of display devices 10 combined with each other may be connected to appear as a single display without obstructing visibility.

For example, when the height H of the black coating layer 260 is lower than the thickness of the encapsulation layer 250, an effect of reducing the brightness may not occur. When the height H of the black coating layer 260 is greater than the thickness of the encapsulation layer 250, a darker line may be recognized between the plurality of display devices 10 that are connected to each other.

For example, when the thickness W of the black coating layer 260 is less than 10 μm, the effect of reducing the brightness may not occur. When the thickness (W) of the black coating layer 260 is greater than 30 μm, a darker line may be recognized between the plurality of display devices 10 that are connected to each other.

As an exemplary embodiment, Table 1 below shows a ratio of the thickness of the black coating layer 260 to the thickness of the encapsulation layer 250 in which the light-emitting element 220 having the above effect is located. As such, a ratio of the thickness of the black coating layer 260 to the thickness of the encapsulation layer 250 may be 2 to 21%. That is, when the ratio of the thickness of the black coating layer 260 to the thickness of the encapsulation layer 250 is less than 2%, the bright line may not be reduced, and when the ratio of the thickness of the black coating layer 260 to the thickness of the encapsulation layer 250 is 21% or more, the dark line may be recognized instead.

TABLE 1

| | | | | Ratio of | Ratio of |
|---|---|---|---|---|---|
| | | Minimum | Maximum | encapsulation | encapsulation |
| | Thickness of | thickness of | thickness of | layer-black | layer-black |
| | encapsulation | black coating | black coating | coating layer | coating layer |
| NO. | layer (μm) | layer (μm) | layer (μm) | (%) | (%) |
| 1 | 140 | 10 | 30 | 7% | 21% |
| 2 | 220 | 10 | 30 | 5% | 14% |
| 3 | 500 | 10 | 30 | 2% | 6% |

Table 2 below shows a relationship between the thickness W of the applied black coating layer 260 and the brightness of light emitted by the light-emitting element 220, which is related to the phenomenon in which the joint portion of the display device 10 appears as a brighter line than the other surfaces.

When the thickness W of the black coating layer 260 is 10 μm, the brightness by the light-emitting element 220 may be 650 nit, when the thickness W of the black coating layer 260 is 20 μm, the brightness by the light-emitting element 220 may be 580 nit, and further, when the thickness W of the black coating layer 260 is 30 μm, the brightness by the light-emitting element 220 may be 460 nit. As such, it may be seen that the brightness decreases as the thickness W of the black coating layer 260 increases. In the present embodiment, for example, when the thickness W of the black coating layer 260 increases by 1 μm, the brightness may decrease by 15 to 65 nits.

TABLE 2

| | | | Brightness/black |
|---|---|---|---|
| | Black coating | Brightness | coating layer |
| NO. | layer | (nit) | thickness (nit/μm) |
| 1 | 10 | 650 | 65 |
| 2 | 20 | 580 | 29 |
| 3 | 30 | 460 | 15 |

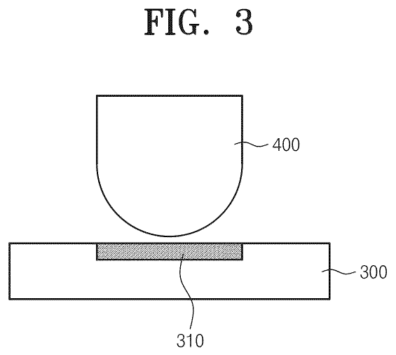

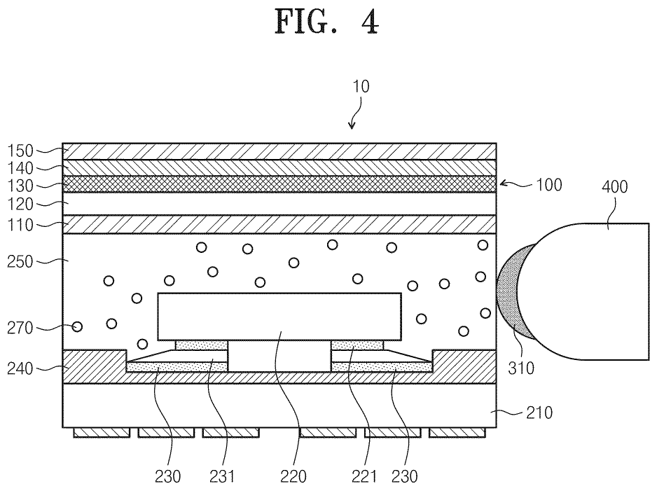

FIG. 3 and FIG. 4 are schematic cross-sectional views showing a process of manufacturing a display device according to the first embodiment of the present disclosure.

Hereinafter, with reference to FIGS. 3 and 4, the process of manufacturing the display device 10 according to the first embodiment will be described.

As described above, the black coating layer 260 may be formed by applying a base coating agent containing a black pigment. The black coating layer 260 may be formed by a stamping method.

For example, in a state in which an assembly including the electrode pad 230 partitioned on the wiring substrate 210 to form a plurality of unit pixels, the light-emitting element 220 connected to the electrode pad 230, and the encapsulation layer 250 formed on the wiring substrate 210 to cover the light-emitting element 220, the black coating layer 260 may be formed on a lateral surface of the encapsulation layer 250 by stamping a base coating agent including a black pigment.

First, as illustrated in FIG. 3, coating ink 310 filled in an ink jig 300 may be temporarily applied to an end side of a stamp 400. Here, the coating ink 310 may include a black pigment in a resin-based base coating agent.

The base coating agent may have a viscosity of 1,000 to 6,000 centipoise (cps). When the viscosity of the base coating agent is less than or equal to 1,000 cps, the coating ink 310 may flow out after stamping. When the viscosity of the base coating agent is equal to or greater than 6,000 cps, the uniformity of the coating ink 310 may deteriorate.

Then, as shown in FIG. 4, the black coating layer 260 may be formed on the lateral surface of the encapsulation layer 250 via stamping using the stamp 400 to which the coating ink 310 is temporarily applied. As such, the applied coating ink 310 may be cured and/or dried to form the black coating layer 260.

As an exemplary embodiment, the coating ink 310 may include a terminal functional group for improving adhesion to the encapsulation layer 250. For example, the terminal functional group may have a content of 0.001 to 10 wt % with respect to the entire black coating layer 260 after the black coating layer 260 is cured.

As such, to improve uniformity by reducing deviation of the black coating layer 260, the adhesion of the coating ink 310 may be increased to prevent damage to the black coating layer 260 due to external force.

As described above, the content of terminal functional groups (e.g., —OH groups) capable of improving adhesion within the black coating layer 260 may be at least 0.001 wt % and at most 10%. The critical meaning may correspond to a range of a content (0.001 wt %) for obtaining the minimum adhesion and the maximum value (10 wt %) for maintaining the physical properties (hardness and transmittance) of the black coating layer 260 itself.

The black coating layer 260 may have the properties described above. Therefore, repeated explanations are omitted.

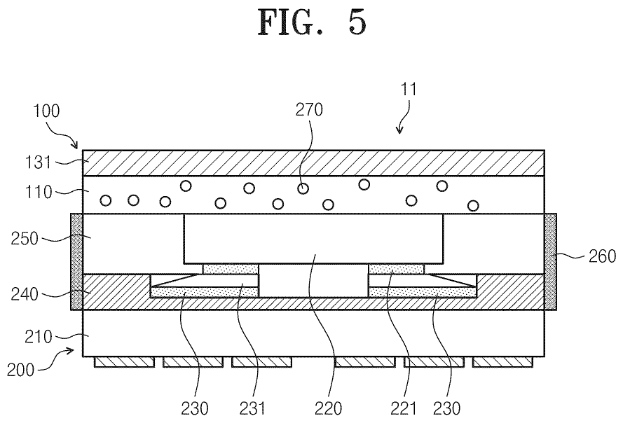

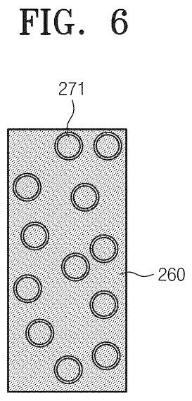

FIG. 5 is a schematic cross-sectional view showing a display device according to a second embodiment of the present disclosure. FIG. 6 is an enlarged view of the black coating layer of FIG. 5.

As illustrated in FIG. 5, the display device 10 may largely include the display panel 200 and the optical layer 100 disposed on the display panel 200.

The display panel 200 may include light-emitting elements 220 arranged on a wiring substrate 210 to form a unit subpixel or pixel. A display image may be implemented by an arrangement of the light-emitting elements 220 that form the unit subpixel or pixel.

As such, the unit subpixel may be configured by separate light-emitting elements 220. For example, the light-emitting elements 220 constituting the unit subpixel may include a red light-emitting element, a green light-emitting element, and a blue light-emitting element.

The separate light-emitting element 220 may be electrically connected to a unit electrode pad 230 located on the wiring substrate 210 by an electric joint such as a solder 231. That is, two electrodes 221 of the light-emitting elements 220 may electrically connected to a pair of unit electrode pads 230, respectively.

The encapsulation layer 250 may be located on the light-emitting element 220. The encapsulation layer 250 may be located on the wiring substrate 210 provided with the electrode pad 230.

The display panel 200 may be the same as the first embodiment described above, and thus repeated explanations are omitted.

The optical layer 100 may be located on the display panel 200. The optical layer 100 may form a composite optical film. As such, the optical layer 100 may be attached to the display panel 200. The display panel 200 to which the optical layer 100 is attached may be referred to as the display device 10.

Here, the optical layer 100 may include, as an exemplary embodiment, the optically transparent adhesive layer (OCA) 110 attached to the display panel 200.

Additionally, a composite optical layer 131 including an anti glare (AG) coating layer and an anti fingerprint (AF) coating layer may be provided on the OCA 110.

For example, the composite optical layer 131 including an anti glare (AG) coating layer and an anti fingerprint (AF) coating layer may be attached to the encapsulation layer 250 by the OCA 110.

For example, the OCA 110 may include the filler 270. The filler 270 may have optical properties that refract or scatter light emitted from the light-emitting element 220.

Light emitted from the light-emitting element 220 may be refracted or scattered by the filler 270. Light scattered from the filler 270 may be emitted to the outside of the OCA 110.

The filler 270 may refract or scatter light that is totally reflected within the encapsulation layer 250. That is, the filler 270 may act as a light scattering agent. Therefore, the filler 270 may be called a light scattering agent. Repeated explanations of the filler 270 are omitted.

A black coating layer 260 containing black pigment within a resin-based base coating agent may be located on a lateral surface of the encapsulation layer 250. Here, the base coating agent may include acrylic, silicone, or acrylic resin.

As an exemplary embodiment, the black pigment in the black coating layer 260 may have a content of 0.01 to 5 wt %. For example, the black coating layer 260 may be formed by applying a base coating agent containing a black pigment.

After the base coating agent containing the black pigment is cured, the black pigment in the black coating layer 260 may have a content of 0.01 to 5 wt %.

FIG. 6 schematically enlarges and illustrates the black coating layer 260. As an exemplary embodiment, separate particles 271 of the black pigment within the black coating layer 260 may have a size of 20 nm to 3 μm.

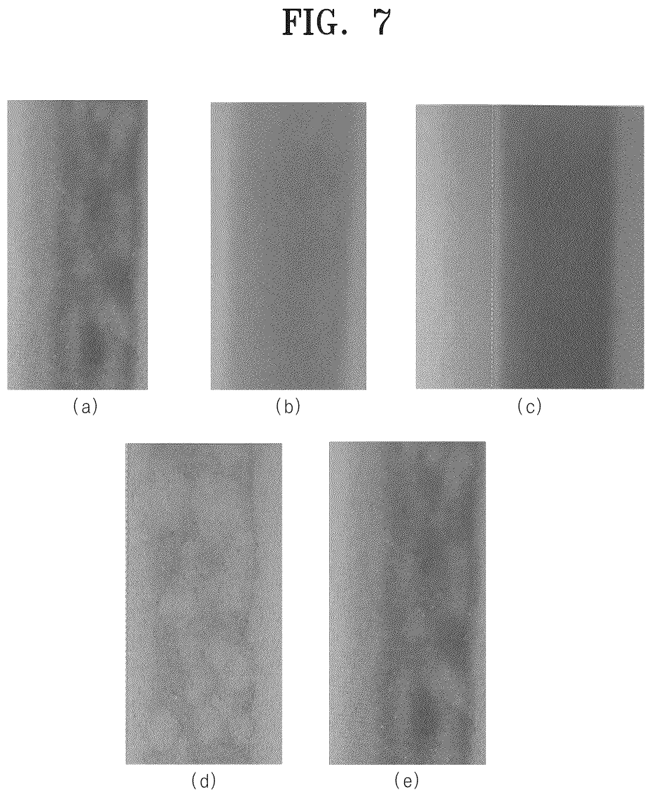

FIG. 7 is a photograph showing examples of a black coating layer formed by a stamping process.

FIG. 7 shows a shape of the black coating layer 260 for each coating ink formed by a stamping method. That is, there may be differences in the shape of the black coating layer 260 formed depending on a type of ink used.

As such, the black coating layer 260 may be formed using various inks. In this example, in cases (a) and (c), the black coating layer 260 having the characteristics described above may be used.

FIG. 8 is a cross-sectional view showing a display device according to the second embodiment of the present disclosure.

FIG. 8 shows a unit module display device 12 in a state in which the plurality of light-emitting elements 220 are provided to form pixels or subpixels in the display device 11 described with reference to FIG. 5.

FIG. 8 illustrates a state in which three light-emitting elements 220 are provided, but a greater number of light-emitting elements 220 may be provided in a unit display device 12.

In this case, the encapsulation layer 250 covering the plurality of light-emitting elements 220 may be provided. The black coating layer 260 may be located on an end side of the encapsulation layer 250.

As such, when unit display devices 12 having the black coating layer 260 at an end side thereof are combined with each other to form a larger display device, a phenomenon in which a joint portion of the display devices 12 appears as a bright line compared to the other surface may be prevented. Accordingly, the plurality of display devices 12 combined with each other may be connected to appear as a single display without obstructing visibility.

The features, structures, effects, and the like described in the above embodiments are included in at least one embodiment of the present invention and are not necessarily limited to only one embodiment. Furthermore, those features, structures, and effects exemplified in each embodiment may be combined or modified in other embodiments by those skilled in the art to which the embodiments pertain. Therefore, such combinations and modifications should be construed as falling within the scope of the present invention.

Although the invention has been described with reference to specific embodiments, such embodiments are merely illustrative and are not intended to limit the scope of the invention. It will be understood by those skilled in the art that various modifications and applications not specifically illustrated herein are possible without departing from the essential characteristics of the present invention. For example, each of the elements specifically described in the embodiments may be implemented in a modified form. Differences related to such modifications and applications should also be construed as being within the scope of the invention as defined by the appended claims.

### INDUSTRIAL APPLICABILITY

According to the present disclosure, a display device and a method for manufacturing the display device using a semiconductor light emitting device may be provided.

1. A display device comprising:
a wiring substrate;
an electrode pad partitioned on the wiring substrate to form a plurality of unit pixels;
a light-emitting element connected to the electrode pad;
an encapsulation layer formed on the wiring substrate to cover the light-emitting element;
a black coating layer located on a lateral surface of the encapsulation layer and including a black pigment in a resin-based base coating agent; and
an optical layer located on the encapsulation layer.

2. The display device of claim 1, wherein the base coating agent includes acrylic, silicone, or acrylic resin.

3. The display device of claim 1, wherein the black pigment in the black coating layer has a content of 0.01 to 5 wt %.

4. The display device of claim 1, wherein separate particles of the black pigment have a size of 20 nm to 3 μm.

5. The display device of claim 1, wherein a height of the black coating layer corresponds to a thickness of the encapsulation layer.

6. The display device of claim 1, wherein a thickness of the black coating layer is 10 to 30 μm.

7. The display device of claim 6, wherein a ratio of a thickness of the black coating layer to a thickness of the encapsulation layer is in the range of 2 to 21%.

8. The display device of claim 1, further comprising a light scattering agent distributed in at least one of the encapsulation layer or the optical layer.

9. The display device of claim 8, wherein the light scattering agent includes at least one of zirconium (Zr), silicon (Si), titanium (Ti), zinc (Zn), BaS, or an oxide thereof.

10. The display device of claim 1, wherein the optical layer includes:
an optically transparent adhesive layer; and
an anti glare (AG) and anti fingerprint (AF) functional coating located on the optically transparent adhesive layer.

11. A method of manufacturing a display device, the method comprising:
providing an assembly including a wiring substrate, an electrode pad partitioned on the wiring substrate to form a plurality of unit pixels, a light-emitting element connected to the electrode pad, and an encapsulation layer formed on the wiring substrate to cover the plurality of light-emitting elements; and
forming a black coating layer by stamping coating ink including a black pigment in a resin-based base coating agent on a lateral surface of the encapsulation layer.

12. The method of claim 11, wherein the coating ink includes a terminal functional group for improving adhesion to the encapsulation layer.

13. The method of claim 12, wherein the terminal functional group has a content of 0.001 to 10 wt % with respect to the entire black coating layer.

14. The method of claim 11, wherein the black pigment in the black coating layer has a content of 0.01 to 5 wt %.

15. The method of claim 11, wherein separate particles of the black pigment have a size of 20 nm to 3 μm.
